(19) United States
(12) Patent Application Publication
(10) Pub. No.: US 2010/0323124 A1
(43) Pub. Date: Dec. 23, 2010

(54) SEALED PLASMA COATINGS

(75) Inventors: Ara Vartabedian, Hudson, MA (US); Marc Abouaf, Harvard, MA (US); Stephen W. Into, Harvard, MA (US); Matthew A. Simpson, Sudbury, MA (US)

Correspondence Address: LARSON NEWMAN & ABEL, LLP, 5914 WEST COURTYARD DRIVE, SUITE 200, AUSTIN, TX, 78730, US

(73) Assignee: SAINT-GOBAIN CERAMICS & PLASTICS, INC., Worcester, MA (US)

(21) Appl. No.: 12/814,107

(22) Filed: Jun. 11, 2010

Related U.S. Application Data
(60) Provisional application No. 61/218,598, filed on Jun. 19, 2009.

(51) Int. Cl. C23C 16/458; H01L 21/683; C23C 16/00

(52) U.S. Cl. 427/569; 361/234; 118/723 R

(57) ABSTRACT

A processing device includes a plurality of walls defining an interior space configured to be exposed to plasma and a surface coating on the interior surface of at least one of the plurality of walls. The surface coating includes pores forming interconnected porosity. The processing device further includes a sealant residing in at least a portion of the pores of the surface coating. In an embodiment, the sealant can be a thermally cured sealant having a cure temperature not greater than about 100° C. In another embodiment, the sealant can be an epoxy sealant having a viscosity of not greater than 500 cP in liquid precursor form. In yet another embodiment, the sealant can be a low shrinkage sealant characterized by a solidification shrinkage of not greater than 8%.

### CROSS-REFERENCE TO RELATED APPLICATION(S)

The present application claims priority from U.S. Provisional Patent Application No. 61/218,598, filed Jun. 19, 2009, entitled “Sealed plasma coatings,” naming inventors Ara Vartabedian, Marc Abouaf, Stephen W. Into and Matthew A. Simpson, which application is incorporated by reference herein in its entirety.

### BACKGROUND

1. Field of the Disclosure

This disclosure is directed to sealed plasma coatings and is particularly directed to sealed plasma coatings for electrostatic chucks and plasma chamber walls for use in processing of flat panel display glass and semiconductor wafers.

2. Description of the Related Art

During semiconductor processing, various steps involve the use of plasmas, such as plasma etch, plasma-enhanced chemical vapor deposition (PECVD) and resist strip. The equipment required for these processes must operate within an environment inside the plasma chamber. Inside the plasma chamber, the equipment can be exposed to plasma, etchant gasses, and thermal cycling. Accordingly, to increase the lifetime of the equipment and to reduce contamination, it is important for the equipment to be erosion and corrosion resistant to the process gases and plasma. In some process chamber environments, for example, halogen containing high-density plasma-etching chamber environments, conditions are highly aggressive, causing erosion of various chamber components, including chamber walls, liners, process kits, dielectric windows, and chucks.

One particularly important chamber component is the chuck used to support and hold wafers and substrates in place within high temperature and corrosive processing chambers. Several main types of chucks have been developed. Mechanical chucks stabilize wafers on a supporting surface by using mechanical holders. Mechanical chucks have a disadvantage in that they often cause distortion of workpieces due to non-uniform forces being applied to the wafers. Thus, wafers are often chipped or otherwise damaged, resulting in a lower yield. Vacuum chucks operate by lowering the pressure between the wafer and the chuck below that of the chamber, thereby holding the wafer. Although the force applied by vacuum chucks is more uniform than that applied by mechanical chucks, improved flexibility is desired. In this respect, pressures in the chamber during semiconductor manufacturing processes tend to be low, and sufficient force cannot always be applied.

Recently, electrostatic chucks (ESCs) have been used to hold workpieces in a processing chamber. Electrostatic chucks work by utilizing a voltage difference between the workpiece and electrodes that can be embedded in the body of the electrostatic chuck, and may apply a more uniform force than mechanical chucks.

Broadly, there exist two types of ESCs: a unipolar type and a bipolar type. The unipolar, or parallel plate ESC includes a single electrode and relies upon plasma used within the processing chamber to form the second “electrode” and provide the necessary attractive forces to hold the substrate in place on the chucking surface. The bipolar, or integrated electrode ESC, includes two electrodes of opposite polarity within the chuck body and relies upon the electric field generated between the two electrodes to hold the workpiece in place.

Additionally, in an ESC, the chucking of a wafer can be achieved using a Coulombic force or Johnsen-Rahbek (JR) effect. Chucks using a JR effect use a resistive layer between the electrode and the workpiece, particularly in workpieces that are semiconductive or conductive. The resistive layer has a particular resistivity, typically less than about 10¹⁰ Ohm-cm, to allow charges within the resistive layer to migrate during operation. That is, during operation of a JR effect ESC, charges within the resistive layer migrate to the surface of the chuck and charges from the workpiece migrate toward the bottom surface thereby generating the necessary attractive electrostatic force. In contrast, ESCs utilizing a Coulombic effect rely upon the embedded electrode as essentially one plate of a capacitor and the workpiece (or plasma) as the second plate of a capacitor, and a dielectric material between the plates. When a voltage is applied across the workpiece and the electrode, the workpiece is attracted to the surface of the chuck.

To protect the chamber components from the processing chamber environments, a barrier coating can be applied to the exposed surfaces. U.S. Pat. No. 6,592,707 to Shih et al. describes a methacrylate containing polymer coating that can be applied to the exposed surfaces of the processing chamber to protect from the effects of the plasma. The polymer coating can be applied to a bare surface or overtop a ceramic barrier layer. Alternatively, US Publication 2004/0216667 describes protecting processing chamber components by sealing a thermally sprayed barrier layer with a resin such as silicon, polytetrafluoroethylene, polyimide, polyamideimide, polyetherimide, polydenzimidazole, or perfluoroalkoxyalkane. The resin seals the pores of the thermally sprayed barrier layer preventing the harsh chemicals from penetrating the barrier layer and attacking the underlying metal. US Publication 2008/0169588 describes yet another approach in which a thermally sprayed coating is sealed with a methacrylate containing polymer. A methacrylate containing solution having a low viscosity is infiltrated into the pores of the thermally sprayed coating and cured in the absence of oxygen.

Despite improvements in chamber components, various industries continue to demand improved performance, for example, those industries processing larger, more massive substrates and workpieces. Notably, the glass industry and particularly the flat panel display (FPD) industry are moving rapidly to produce displays of larger size. Indeed, currently chucks are demanded that have dimensions in excess of two meters by two meters. This shift to processing of larger workpieces, generally within high temperature and corrosive processing environments, places further demands on chamber components used during processing.

### SUMMARY

According to a first aspect, a processing device can include a plurality of walls defining an interior space configured to be exposed to plasma, and a surface coating on the interior surface of at least one of the plurality of walls. The surface coating comprising pores forming interconnected porosity. The processing device can further include a sealant residing within at least a portion of the pores of the surface coating. In a particular embodiment, the sealant can be a thermally cured sealant having a cure temperature not greater than about 120° C. In another particular embodiment, the sealant can be an epoxy sealant having a viscosity of not greater than 500 cP in liquid precursor form. In yet another particular embodiment, the sealant can be a low shrinkage sealant characterized by a solidification shrinkage of not greater than 8%.

According to a second aspect, an electrostatic chuck can include an insulating layer, a conductive layer overlying the insulating layer, and a dielectric layer overlying the conductive layer. The insulating layer can have an aspect ratio of at least 1.1, and the dielectric layer can include pores forming interconnected porosity. The aspect ratio is the ratio of the length to the width of the chucking surface of the electrostatic chuck. The electrostatic chuck can further include a sealant residing in at least a portion of the pores of the dielectric layer. In a particular embodiment, the sealant can be a thermally cured sealant having a cure temperature not greater than about 120° C. In another particular embodiment, the sealant can be an epoxy sealant having a viscosity of not greater than 500 cP in liquid precursor form. In yet another particular embodiment, the sealant can be a low shrinkage sealant characterized by a solidification shrinkage of not greater than 8%.

In a third aspect, a method of forming a processing device can include providing a substrate, and forming a surface coating overlying the substrate. The surface coating can include pores forming interconnected porosity. The method can further include infiltrating the surface coating with an infiltrant including a sealant, and curing the infiltrant such that the sealant is left to reside in at least a portion of the pores. In a particular embodiment, the curing can include thermally curing at a temperature of not greater than about 120° C. In another particular embodiment, the sealant can be an epoxy sealant having a viscosity of not greater than 500 cP during infiltrating. In yet another particular embodiment, the sealant can be a low shrinkage sealant characterized by a solidification shrinkage of not greater than 8%.

In another aspect, a method of forming an electronic device can include providing an electrostatic chuck defining a work surface, providing a workpiece overlying the work surface, providing a voltage across the electrostatic chuck and the workpiece to maintain the workpiece in proximity to the work surface; and processing the workpiece to form an electronic device. The electrostatic chuck can include (i) an insulating layer having an aspect ratio of at least 1.1, (ii) a conductive layer overlying the insulating layer, (iii) a dielectric layer have pores forming interconnected porosity overlying the conductive layer, and (iv) a sealant residing in the pores of the dielectric layer. In a particular embodiment, the sealant can be a thermally cured sealant having a cure temperature not greater than about 120° C. In another particular embodiment, the sealant can be an epoxy sealant having a viscosity of not greater than 500 cP in liquid precursor form. In yet another particular embodiment, the sealant can be a low shrinkage sealant characterized by a solidification shrinkage of not greater than 8%.

### BRIEF DESCRIPTION OF THE DRAWINGS

The present disclosure may be better understood, and its numerous features and advantages made apparent to those skilled in the art by referencing the accompanying drawings.

FIG. 1 is a cross-sectional illustration of an electrostatic chuck according to an embodiment.

FIG. 2 is an SEM micrograph illustrating the morphology of a thermally sprayed layer in accordance with an embodiment.

FIG. 3 illustrates a configuration of constituent layers according to an embodiment.

FIG. 4 is a cross-sectional illustration of an electrostatic chuck according to one embodiment.

FIG. 5 is a cross-sectional illustration of plasma chamber wall according to an embodiment.

FIG. 6 is a cross-sectional illustration of plasma chamber according to an embodiment.

FIG. 7 is a graph representing infiltrant retention subjected to etch conditions.

The use of the same reference symbols in different drawings indicates similar or identical items.

### DESCRIPTION OF THE EMBODIMENT(S)

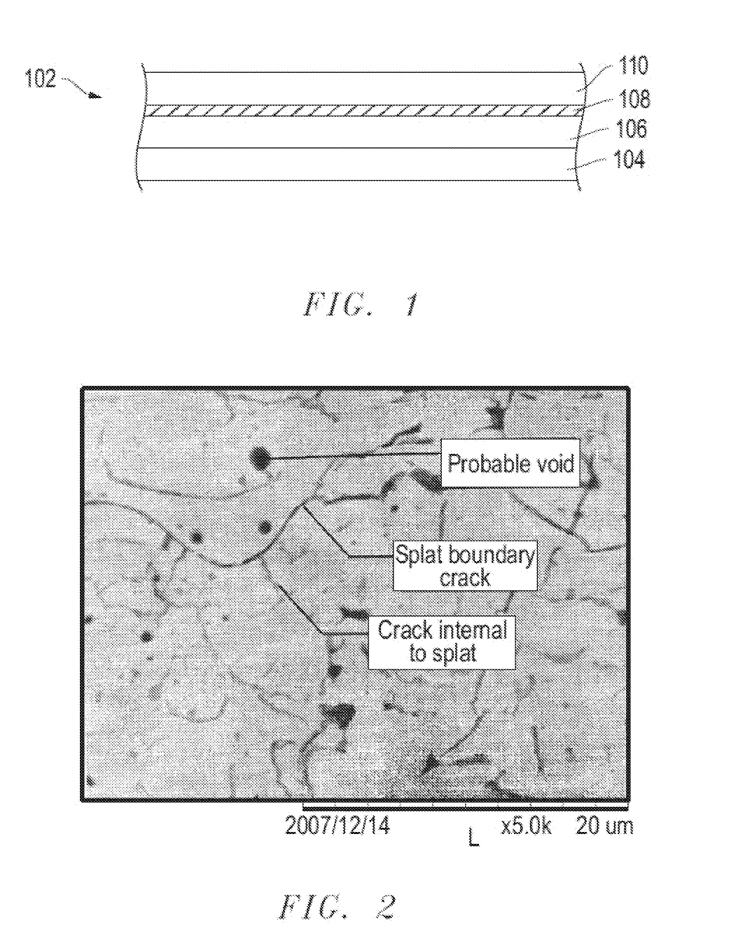

Referring to FIG. 1, an electrostatic chuck 102 is illustrated having several constituent layers. The electrostatic chuck 102 includes a base 104, supporting several layers, an insulating layer 106, a conductive layer 108, and a dielectric layer 110. The base 104 is provided for mechanical support of the overlying layers, and may be chosen from any one of several classes of materials that offer appropriate thermal and mechanical characteristics such as thermal conductivity, stiffness, toughness, and strength, and which can withstand processing temperatures associated with the formation of the overlying layers. Certain embodiments make use of metal alloys, such as iron, nickel or aluminum alloys. Aluminum alloys are particularly suitable.

In an embodiment, the electrostatic chuck 102 can have a total thickness of less than about 50 mm. Further, the electrostatic chuck can have a warp of less than 200 um, such as less than 175 um, even less than 150 um, over a length of 700 mm. Warp is defined as the difference between the maximum and minimum distances of the chucking surface of the electrostatic chuck. Additionally, the electrostatic chuck 102 can have a Normalized Warp of not greater than about 33, such as not greater than about 30, even not greater than about 25. Normalized Warp is defined by W*=W*E*(t/d)²/t_{d}, where E is the elastic modulus in GPa, d is the measurement length in mm, t is the substrate thickness in mm, t_{d} is the dielectric thickness in mm, and W is the difference between the maximum and minimum distances of the chucking surface in microns.

Although the embodiment shown in FIG. 1 includes a base, self-supporting electrostatic chucks can omit such a structure. However, in the context of large-sized electrostatic chucks utilized in the flat panel display (FPD) industry, which can have a surface area of greater than about 4 m², generally a base is utilized to provide an appropriate mechanical template for formation of the overlying layers.

The insulating layer can be ceramic-based, typically exhibiting high resistivity values to resist migration of charges from the overlying conductive layer 108 to the base 104, known as leakage current. As used herein, description of a ‘base’ composition generally refers to a base material that accounts for at least 50 weight percent of the layer, typically greater then 60 weight percent, such as greater then 70 or 80 weight percent. According to embodiments, the insulating layer can have a volume resistivity of not less than 10¹¹ ohm-cm, such as not less than about 10¹³ ohm-cm. The insulating layer can have an average thickness greater than about 100 microns, such as greater than about 200 microns. Typically, the thickness of the insulating layer is limited, such as less than 1500 microns. The ceramic-base for forming the insulating layer can include various metal oxide ceramics, such as aluminum-containing oxides, silicon-containing oxides, zirconium-containing oxides, titanium-containing oxides, yttria-containing oxides, and combination or compound oxides thereof. More specifically, embodiments can utilize a material selected from the group consisting of aluminum oxide, zirconium oxide, yttrium oxide, titanates, and silicates (though typically not silica, SiO₂).

According to embodiments of the present invention, the insulating layer is a depositional coating. Depositional coatings include thin-film and thick film coatings. Thin film coatings generally involve deposition of a material atom-by-atom or molecule-by-molecule, or by ion deposition onto a solid substrate. Thin-film coatings generally denote coatings having a nominal thickness less than about 1 micron, and most typically fall within fairly broad categories of physical vapor deposition coatings (PVD coatings), and chemical vapor deposition coatings (CVD coatings), and atomic layer deposition (ALD).

While depositional coatings broadly include both thick and thin film coatings, embodiments herein can take advantage of thick film coatings, such as thermal spray coatings, particularly given the mass and thickness requirements of constituent layers. Thermal spraying includes flame spraying, plasma arc spraying, electric arc spraying, detonation gun spraying, and high velocity oxy/fuel spraying. Particular embodiments have been formed by depositing the layer utilizing a flame spray technique, and in particular, a flame spray technique utilizing the Rokide® process, which utilizes a Rokide® flame spraying spray unit. In this particular process, a ceramic material formed into the shape of a rod is fed into a Rokide® spray unit at a constant and controlled feed rate. The ceramic rods are melted within the spray unit by contact with a flame that is generated from oxygen and acetylene sources, atomized, and sprayed at a high velocity (such as on the order of 170 m/s) onto the substrate surface. The particular composition of the ceramic rod can be chosen based on dielectric and resistivity properties. According to the Rokide® process, fully molten particles are sprayed onto the surface of the substrate, and the spray unit is configured such that particles are not projected from the spray unit until being fully molten. The kinetic energy and high thermal mass of the particles maintain the molten state until reaching the substrate.

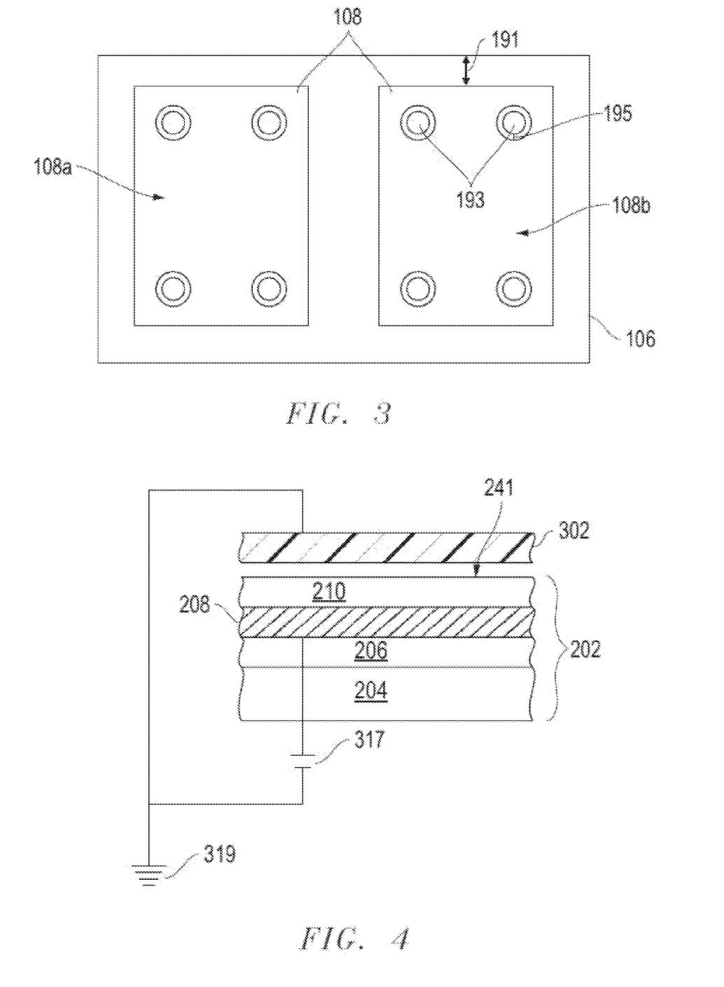

Further, the insulating layer can be porous, particularly having interconnected porosity, such as a porosity within a range of about 2% to 10% by volume. In the particular case of a thermally sprayed insulating layer, this porosity may be defined by the splat formations that are characteristic to the thermal spray process. Particularly, the pores can be interconnected and extend between the splat formations. In this respect, reference is made to FIG. 2 showing an SEM photograph of a thermally sprayed alumina layer, which has a porosity of about 5 vol. %. As can be seen, pores are defined between the splat formations, and the pores are interconnected through channels extending along splat lines.

The conductive layer 108 can also be a depositional coating as described above. Certain embodiments call for a thick film deposition process such as printing or a spraying (e.g., thermal spraying). As above, in the context of a thermal spraying process, plasma spraying or wire gun spraying may be utilized. In connection with an underlying thermally sprayed insulating layer, the conductive layer 108 is desirably thermally sprayed as well.

The conductive layer 108 is generally thinner relative to the insulating layer 106. According to one embodiment, the conductive layer 108 has an average thickness of not greater than about 100 microns, such as not greater than about 75 microns, and in some cases not greater than about 50 microns. In one particular embodiment, the conductive layer 108 has an average thickness within a range of between about 10 microns and about 50 microns. Additionally, the conductive layer 108 is embedded within the electrostatic chuck, such that it is bounded on all sides by the insulating layer below, the dielectric layer above, and a peripheral boundary region on the peripheral edges. In an embodiment, the outer peripheral edge of the conductive layer can be at least about 1 mm from the outer peripheral surface of the electrostatic chuck. That is, the boundary region extends at least 1 mm on all sides of the peripheral edge of the conductive layer.

In reference to the materials suitable for forming the conductive layer 108, generally the conductive layer 108 is formed of a conductive material, particularly inorganic materials, such as a conductive metal, or metal alloy. Suitable metals can include high temperature metals such as titanium, molybdenum, nickel, copper, tungsten, iron, silicon, aluminum, noble metals and combinations or alloys thereof. In one particular embodiment, the conductive layer 108 includes molybdenum, tungsten or a combination thereof. Moreover, particular embodiments utilize a conductive layer 108 having not less than about 25 wt % metal, such as not less than about 50 wt % metal. According to another embodiment, the conductive layer 108 includes not less than about 75 wt % metal, such as not less than about 90 wt % metal, and even in some instances, the conductive layer 108 is made entirely of metal. The foregoing description of metal includes elemental metals and metal alloys.

The conductive layer 108 can be a composite material, and as such, in addition to the conductive material, the conductive layer 108 can contain adhesion promoters. Such adhesion promoters can be inorganic materials. Particularly suitable adhesion promoters can include oxide-based materials, such as yttrium oxide, aluminum oxide, zirconium oxide, hafnium oxide, titanium oxide, chromium oxide, iron oxide, silicon oxide, barium titanate, tantalum oxide, barium oxide, or compound oxides thereof. According to one particular embodiment, a suitable adhesion promoter contains material species of the underlying layer and/or overlying layer.

Adhesion promoters are generally present within the conductive layer 108 in an amount of less than about 75 vol %. The amount of adhesion promoter can be less, such that the conductive layer 108 contains not greater than about 50 vol %, such as about 25 vol %. In one embodiment, the conductive layer 108 is formed via a thermal spraying process during which the adhesion promoter material is provided simultaneously with the conductor material (e.g., a metal). In one particular embodiment, the conductive layer 108 is formed via a spraying process that utilizes a composite powder composition, which includes the conductor material and the adhesion promoter.

In reference to the electrical properties of the conductive layer 108, the sheet resistance of the conductive layer 108 according to one embodiment is not greater than about 10⁶ ohms, such as not greater than about 10⁴ ohms. According to another embodiment, the sheet resistance of the conductive layer 108 is within a range of between about 10¹ ohms and about 10⁶ ohms.

In further reference to the conductive layer 108, it is generally a continuous layer, conformally deposited over the insulating layer 106. According to one embodiment, the conductive layer 108 is a substantially continuous layer of material. To clarify, the description of ‘substantially continuous’ means that the majority of the surface that is used to attract the workpiece is covered by a conducting surface, which may have pores in it of a size approximately equal to or smaller than the dielectric thickness. That is, small holes can be present in the layer, which can appear in embodiments with high percentages of adhesion promoter, for example, such holes not appreciably affecting chucking force.

Alternatively, the conductive layer 108 can form two isolated regions to respectively form a cathode region 108a and an anode region 108b as shown in FIG. 3. Further, the conductive layer 108 can include a pattern which accommodates features 193 within the layer and extending through the layers, such features can include cooling holes, perforations for facilitating dechucking, electrical contacts, and the like. Notably, the conductive layer 108 can be patterned to provide suitable spacing 195 from such features. According to one embodiment, such spacing is generally greater than about 0.5 mm, such as greater than about 1.0 mm, or even, greater than about 2.0 mm.

The conductive layer 108 can be configured so as to terminate before reaching the edge of the insulating layer 106, which construction may be advantageous to maintain dielectric properties. As such, the conductive layer 108 can be spaced from the edge of the chuck such that a space 191 extends between the edge of the chuck and the conductive layer and extends around the periphery of the conductive layer 108. The average width of this space may be generally greater than about 0.5 mm, such as greater than about 1.0 mm, or even greater than about 2.0 mm.

Turning to the dielectric layer, the dielectric layer can be ceramic-based as well. Such ceramic-based materials include metal oxides, including aluminum-containing oxides, silicon-containing oxides, zirconium-containing oxides, yttria-containing oxides, and insulating titanium-based oxides. In particular, the dielectric material may be selected from the group consisting of aluminum oxide, zirconium oxide, yttrium oxide titanates, and silicates (excluding silica). The dielectric layer can be in the form of thick-film having a thickness not less than about 50 microns, such as not less than about 100 microns, or not less than 200 microns. Certain embodiments have a maximum thickness of about 500 microns. According to a particular feature, the dielectric layer is porous, having pores that form interconnected porosity. That is, the dielectric layer has a network of pores extending into and oftentimes throughout the interior of the body of the dielectric layer, and be accessible from external pores of the dielectric material. The porosity level of the dielectric layer can vary, such as not less than about 1 vol %, oftentimes, not less than about 2 vol %. Suitable porosity ranges can be within a range of about 2 vol. % to 10 vol. %. The pore size of the pores in the dielectric layer is notably fine, generally in the nanometer range. For example, the dielectric layer may have an average pore size of not greater than about 200 nm, such as not greater than about 100 nm.

Generally, optimal chucking properties can be achieved by utilizing a dielectric material having a high dielectric constant (high-k material). As such, the dielectric constant k is generally not less than about 5, such as not less than about 10. Embodiments may utilize even higher dielectric constants, such as not less than about 15, or not less than about 20. Further, embodiments herein provide a dielectric layer having a dielectric strength per unit thickness greater than 10 V/micrometer, and in certain cases greater than 12 V/micrometer, greater than 15 V/micrometer, and even greater than 20 V/micrometer.

According to embodiments of the present invention, the dielectric layer, like the insulating layer, is a depositional coating. Depositional coatings include thin-film and thick film coatings. However, embodiments herein generally utilize thick film coatings, such as thermal spray coatings, given the mass and thickness requirements of constituent layers. Thermal spraying includes flame spraying, plasma arc spraying, electric arc spraying, detonation gun spraying, and high velocity oxy/fuel spraying. Particular embodiments have been formed by depositing the layer utilizing a flame spray technique, and in particular, a flame spray technique utilizing the Rokide® process as described above.

As described above in connection with the insulating layer, the thermally sprayed dielectric layers can be characterized as having particular splat formations, again, reference is made to FIG. 2. In the case of a thermally sprayed dielectric layer, the pores are present between splat formations, and are interconnected with each other along splat lines between individual splat formations and via cracks in the splats themselves.

According to a particular development, the electrostatic chuck 102 is subjected to an infiltration process. Particularly, the electrostatic chuck body is subjected to infiltration with a low viscosity polymer precursor, such as an oligomer or monomer composition provided in a liquid carrier. According to a particular feature, the polymer precursor has a desirably low viscosity, enabling wetting and a high degree of penetration into the interconnected fine porosity of at least the dielectric layer, and optionally the insulating layer. Based on practical studies, the polymer precursor penetrates at least 50 vol % of the porosity, such as at least 65 vol %. As stated above, embodiments may have a particularly fine porous structure, having an average pore size less than 200 nm, such as less than 100 nm. Accordingly, the viscosity of the polymer precursor is typically not greater than 1000 centipoise (cP). Generally, the polymer precursor has a viscosity not greater than 500 cP, such as not greater than 200 cP. Indeed, particular working examples have viscosities less than 100 cP, and even less than 50 cP. Polymer precursors used in accordance with examples provided below, have viscosities on the order of 10 to 30 cP. In an alternate embodiment, particularly when the polymer precursor is an epoxy resin, the polymer precursors can have a viscosity of greater than 50 cP, such as greater than about 55 cP, during the infiltration process.

Additionally, it is desired that the infiltrant formed of the liquid polymer precursor has desirably low shrinkage upon solvent volatilization or vaporization, and curing. Typically, it is desired that the shrinkage from the liquid precursor state to the solid cured state is not greater than 20 vol. %, such as not greater than 15 vol. %, or not greater than 10 vol. %. Solidification shrinkage can be determined by comparing a volume occupied by a sample of the liquid precursor (V₁) to a volume occupied by the solid cured polymer (V_{c}), specifically V₁−V/V₁. In the context of an infiltrated coating, the solidification shrinkage can relate to the volume of the pores filled by the liquid precursor and the volume of the pores filled by the cured infiltrant. It can be particularly advantageous to have a solidification shrinkage of not greater than about 8%, such as not greater than about 5%, even not greater than about 3%. Reduced shrinkages help improve degree of filling of the interconnected porous structure, leaving behind minimized open and unfilled spaces. Based on penetration efficiency and shrinkage, typically at least 40 vol %, such as at least 50 vol % of the pore volume is filled with cured polymer infiltrant. Enhanced filling may be achieved, such as on the order of at least 60 vol %, and in certain embodiments, at least 65 vol % or 70 vol %. For clarity, it is noted that the porosity information provided above for the dielectric layer corresponds to pore volume percentage, ignoring the infiltrant content, that is, prior to infiltration. Pore volume percentages, adjusted for the combination of dielectric material combined with cured polymer infiltrant, are of course lower. For example, a dielectric layer having a porosity of 4 vol %, infiltrated at a loading level of 60% of the pore volume with infiltrant, would have a total or composite porosity of 1.6 vol %. The foregoing is provided for clarification only, and unless otherwise stated, pore volume percentages refer to the as-formed layers prior to infiltration. Thus, in the case of the dielectric layer, the pore volume percentage values are relative to the dielectric ceramic material, not the overall porosity of the dielectric layer. Similarly, in the case of the insulating layer, the pore volume percentage values are relative to the insulating ceramic material, not the overall porosity of the insulating layer.

Liquid polymer precursors may be selected from various polymer families, including acrylates, urethanes and selected epoxy resins. Particular embodiments make use of low viscosity methyl acrylates. However, other particular embodiments make use of epoxy resins. Generally, an epoxy polymer is formed by the reaction of an epoxide resin and a polyamine hardener. The epoxide resin can include monomers, such as bisphenol-A, or short chain polymers having an epoxide functional group at either end. The polyamine hardener can include aliphatic amines such as monoethylamine, diethylenetriamine, triethylenetetraamine, and the like, alicyclic amines, aromatic amines such as cyclicalipheticamines, amidoamines, polyamides, dicynadiamides, imidazole derivatives, and the like, or any combination thereof. Curing involves reaction of the epoxide group with the amine to form a covalent bond. The polymer precursors may be cured by actinic radiation or thermally, although thermal curing is desired to enable complete curing of interior regions of the liquid polymer precursor that actinic radiation cannot reach. In an embodiment, the sealant can have a Plate Warpage of not greater than about 200 um, such as not greater than about 175 um, even not greater than about 150 um.

Solvent based polymer systems can have a high shrinkage due to the loss of the solvent. A high shrinkage can lead to incomplete filling of the pores. Pores with a significant amount of unfilled volume can affect the resulting dielectric and sealing properties of the layer. Thermally cured polymer systems can have a reduced shrinkage rate compared to solvent based polymer systems cross-linked at room temperature.

Certain embodiments, such as methacrylates, when used as a sealant on electrostatic chuck for large FPDs can result in a significant number of unsatisfactory FPDs. The unsatisfactory FPDs can have noticeable changes in color and/or intensity across the FPD. While not wishing to be held to a particular theory, it is believed that the defects are a result of poor dimensional integrity of the electrostatic chuck resulting from high temperature curing of the sealant and/or a high rate of shrinkage of the sealant. The use of sealants having low shrinkage and low cure temperatures can produce electrostatic chucks with an improved dimensional integrity, resulting in a more uniform FPD production with fewer visual defects. A cure temperature of not greater than about 120° C., such as not greater than about 100° C., even not greater than about 65° C., can be particularly advantageous.

Infiltrating may be initiated by simply coating, such as by spraying or brushing, or otherwise immersing the electrostatic chuck in the liquid polymer precursor. Continued processing typically involves subjecting the thus coated or immersed electrostatic chuck to a vacuum, thereby further enhancing pore penetration. Vacuum environments can improve removal of trapped gases in the dielectric layer. Use of a vacuum may be done prior to curing, or simultaneously with curing, such as in a vacuum chamber while heating the thus coated electrostatic chuck. Multiple pumping cycles can be carried out, cycling between a low pressure vacuum environment and atmospheric pressure to enhance penetration. Typical vacuum pressure is on the order of less than 0.25 atm, such as less than 0.1 atm.

In the case of thermal curing, typical thermal cure temperatures generally exceed to 40° C., such as within a range of 50° C. to 250° C. Thermal cure dwell times can range from 5 hours and up. Typically, desirable curing is achieved by 60 hours. Typical cure time periods extend from 10 hours to 40 hours. Depending on the particular curing agent and polymer system, oxygen may be evacuated during curing, to further improve reaction kinetics and promote complete curing of the precursor. Oxygen partial pressures are generally kept below 0.05 atm, such as less than 0.02 atm.

Referring to FIG. 4, a cross-sectional diagram of an electrostatic chuck according to a particular embodiment is illustrated. The chuck includes a base 204 and an insulating layer 206 overlying the base 204. The electrostatic chuck further includes a conductive layer 208 overlying the insulating layer 206, and dielectric layer 210 overlying the conductive layer 208. As also illustrated, a workpiece 302 is being chucked to the working surface 241 of the electrostatic chuck 202. Such a workpiece can be an insulating workpiece such as glass, and particularly a glass panel being processed for a display.

In further reference to FIG. 4, a direct current source 317 is connected to a ground. Notably, the direct current source 317 is connected to the conductive layer 208 and provides the bias necessary to create a capacitor between the conductive layer 205 and the workpiece 302. It will be appreciated that the chucking force will require the utilization of a plasma or other charge source, such as ion or electron gun, within the processing chamber to provide the necessary conductive path to the surface of the workpiece, in order to generate attractive forces to hold the workpiece 302 in place on the chucking surface.

It will be appreciated that while FIG. 2 illustrates a cross-sectional view of the layers, provision of contacts between the conductive layer 208 and cooling channels can be implemented within the electrostatic chuck provided herein. Generally, cooling channels accommodate cooling of the work piece by providing pathways for a cooling gas through the electrostatic chuck to the back surface of the work piece. Such cooling channels can extend through the layers of the ESC, such as from the substrate through to the top surface. Generally, the cooling gas includes an unreactive gas of high thermal conductivity, such as helium.

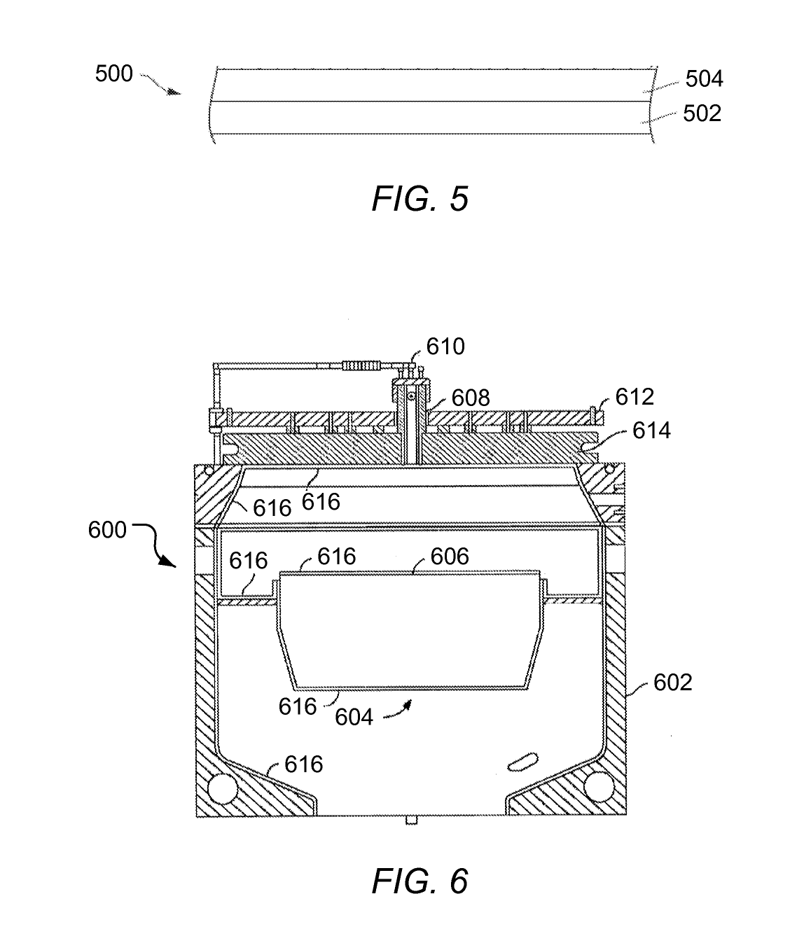

Turning to the construction of the plasma chamber, FIG. 5 illustrates a plasma chamber wall 500. The plasma chamber wall can include a support 502 and a plasma resistant layer 504 overlying the support. The support 502 can be made of quartz or a ceramic material such as alumina. The plasma resistant layer 504 can be similar to the dielectric layer described above with respect to the electrostatic chuck. In an embodiment, the plasma resistant layer 504 can be a ceramic-based layer. Such ceramic-based materials include metal oxides, including aluminum-containing oxides, silicon-containing oxides, zirconium-containing oxides, yttrium-containing oxides, and insulating titanium-based oxides. In particular, the plasma resistant material may be selected from the group consisting of aluminum oxide, zirconium oxide, yttrium oxide, titanates, and silicates (excluding silica). The plasma resistant layer can be in the form of thick-film having a thickness not less than about 50 microns, such as not less than about 100 microns, or not less than 200 microns. Certain embodiments have a maximum thickness of about 500 microns. According to a particular feature, the plasma resistant layer is porous, having pores that form interconnected porosity. That is, the plasma resistant layer has a network of pores extending into and oftentimes throughout the interior of the body of the plasma resistant layer, and be accessible from external pores of the plasma resistant material. The porosity level of the plasma resistant layer can vary, such as not less than about 1 vol %, oftentimes, not less than about 2 vol %. Suitable porosity ranges can be within a range of about 2 vol. % to 10 vol. %. The pore size of the pores in the plasma resistant layer is notably fine, generally in the nanometer range. For example, the plasma resistant layer may have an average pore size of not greater than about 200 nm, such as not greater than about 100 nm.

According to embodiments of the present invention, the plasma resistant layer, like the dielectric layer of the electrostatic chuck, is a depositional coating. Depositional coatings include thin-film and thick film coatings. However, embodiments herein generally utilize thick film coatings, such as thermal spray coatings, given the mass and thickness requirements of constituent layers. Thermal spraying includes flame spraying, plasma arc spraying, electric arc spraying, detonation gun spraying, and high velocity oxy/fuel spraying. Particular embodiments have been formed by depositing the layer utilizing a flame spray technique, and in particular, a flame spray technique utilizing the Rokide® process as described above.

As described above in connection with the insulating layer, the thermally sprayed plasma resistant layers can be characterized as having particular splat formations, again, reference is made to FIG. 2. In the case of a thermally sprayed plasma resistant layer, the pores are present between splat formations, and are interconnected with each other along splat lines between individual splat formations and via cracks in the splats themselves.

According to a particular development, the plasma chamber wall is subjected to an infiltration process. Particularly, the plasma chamber wall is subjected to an infiltration process similar to the infiltration process described above with respect to the electronic chuck.

Referring to FIG. 6, a schematic diagram of a plasma reactor 600 according to a particular embodiment is illustrated. The reactor 600 comprises a chamber 602 that includes a substrate support 604 including an electrostatic chuck 606, which provides a clamping force to a substrate such as a flat panel display (not shown) mounted thereon. Processing gases are introduced into the chamber 602 via a gas injector 608 located on the top of chamber 602 and connected to a gas feed 610. As shown, an inductive coil 612 can be provided to couple RF energy through dielectric window 614 into the interior of chamber 602. The chamber 602 can also include suitable vacuum pumping apparatus (not shown) for maintaining the interior of the chamber at a desired pressure.

Selected internal surfaces of reactor components, such as the dielectric window 614, the substrate support 604, the electrostatic chuck 606, are shown coated with a plasma resistant coating 616. Additionally, selected interior surfaces of the chamber 602 can also be provided with a plasma resistant coating 616. Any or all of these surfaces, as well as any other internal reactor surface, can be provided with a plasma resistant coating.

In an embodiment, the surface layer, such as the dielectric layer or the plasma resistant layer, can have a liquid particle count of not greater than about 10,000 particles/cm2, such as not greater than about 7,500 particles/cm2, even not greater than about 5,000 particles/cm2. In a further embodiment, the surface layer can have an acid etch resistance rating of at least about 750 minutes, such as at least about 1000 minutes, even at least about 1250 minutes.

In an embodiment, the surface coating can include yttrium oxide. Additionally, the surface coating can have a hardness of at least about 4.5 GPa, such as at least about 4.7 GPa, even at least about 4.9 GPa. Further, the surface coating can have a Young's Modulus of at least about 70 GPa, such as at least about 80 GPa, even at least about 85 GPa. Further, the surface coating can have an adhesion strength of at least about 40 MPa, such as at least about 50 MPa, even at least about 60 MPa.

In another embodiment, the surface coating can include aluminum oxide. Additionally, the surface coating can have a hardness of at least about 10.6 GPa, such as at least about 10.7 GPa, even at least about 10.8 GPa. Further, the surface coating can have a Young's Modulus of at least about 130 GPa, such as at least about 140 GPa, even at least about 150 GPa. In a particular embodiment, the surface coating can have a adhesion strength of at least about 70 MPa, such as at least about 75 MPa, even at least about 80 MPa on an anodized aluminum substrate. In another particular embodiment, the surface coating can have an adhesion strength of at least about 40 MPa, such as at least about 50 MPa, even at least about 60 MPa on a bare aluminum substrate.

The present disclosure also provides a method of forming an electronic device using an electrostatic chuck or plasma processing device as described in embodiments herein. Here, the chucked workpiece assembly shown in FIG. 4 is provided within the processing chamber. The workpiece can generally include an inorganic material and particularly is formed principally of a glass phase, such as a silicate-based glass. According to one embodiment, the workpiece is a display panel, intended for final application as a video display. Such video displays can include liquid crystal displays (LCDs), plasma displays, electroluminescent displays, displays utilizing thin-film-transistors (TFTs), and the like. Other workpieces can include semiconductor wafers, such as silicon-based wafers.

Generally, the workpieces can be large and in some cases, have rectangular shape (including square), with length and width dimensions not less than about 0.25 m, such as not less than about 0.5 m or even not less than about 1.0 m. The electrostatic chuck can be similarly sized, and indeed have a working surface of a generally rectangular contour and having a surface area not less than 3 m². Additionally, the working surface can have an aspect ratio, the ratio of the length to the width, of at least about 1.2, such as at least about 1.3, even at least about 1.5.

Processing of the workpiece can include chemical processing, such as a photolithography and chemical processing, and more particularly can include a masking, etching, or deposition process, or a combination of all such processes. In one embodiment, processing of the workpiece includes etching, such as a plasma etching process. According to another embodiment, processing of the workpiece includes a thin-film deposition process, such as one utilizing a vapor deposition process, such as chemical vapor deposition (CVD), and particularly a plasma assisted CVD process.

According to one embodiment, processing of the workpiece includes forming electronic devices on the workpiece, such as transistors, and more particularly, processing of the workpiece includes forming a series of transistors, or an array of transistors, such as a TFT. As such, the workpiece can undergo multiple masking, deposition and etching processes. Moreover, such a process can include deposition of metals, semiconductive materials, and insulating materials.

Generally, such processing is undertaken at reduced pressures, and according to one embodiment, processing of the workpiece is done at a pressure of not greater than about 0.5 atm, such as not greater than about 0.3 atm, or not greater than about 0.1 atm.

### EXAMPLES

The following examples based are based on coupons samples to illustrate concepts of present invention. It is understood that commercial samples would be in the form of completed electrostatic chucks having the requisite features for usage.

Example 1, comparative samples, no infiltration.

Four 6061 aluminum squares 4 cm on a side were grit blasted, plasma sprayed with aluminum oxide to a thickness of about 500 um to provide a porosity about 5%, and then plasma sprayed with tungsten on top to a thickness of about 50 um.

The samples were tested by applying a steadily increasing DC voltage between the tungsten and the base aluminum and monitoring current. Breakdown was deemed to occur when the current exceeded 2 mA.

TABLE 1

| Comparative Sample | Breakdown voltage (kV) |
|---|---|
| H | 2.5 |
| K | 10.3 |
| N | 4.7 |
| O | 2.1 |

The breakdown voltage varies, with a mean value of only 4.9 kV

Example 2, samples with infiltration.

Three samples were prepared as for example 1, but with the following addition. HL-126 acrylate monomer (obtained from Permabond LLC of Pottstown, Pa.) was painted onto the surface after spraying. Generous amounts were applied, so that the surface looked well wetted even after a minute or so was allowed for the liquid to soak into the pores. The samples were placed into a vacuum oven and several cycles of evacuation followed by backfill with argon were conducted. This served two purposes: the HL-126 was driven further into the pores and oxygen (which inhibits the cure of the monomer) was removed from the oven.

Samples were cured for about 2 hours at 120° C. They were then removed from the oven and an area over the tungsten was ground clean so that electrical contact could be established to the tungsten. The samples were then tested as in Example 1, with a maximum applied voltage of 10 kV.

In no case did breakdown occur, indicating the average breakdown voltage exceeds 10 kV.

Example 3, additional characterization.

An important attribute of the infiltration process is that infiltrant not be removed by plasma gases. It was found unexpectedly that the infiltrant stays intact for a long time under etch conditions.

A set of coupons was plasma sprayed with yttrium oxide to a thickness of 100 um using a process that produces 4-5% porosity. They were infiltrated with HL-126 as described in Example 2 above.

The coupons were etched in a March PM-600 plasma asher (March Plasma Systems Inc., Concord, Calif.), with oxygen at 300 W, 250 millitorr for extended times. The amount of infiltrant was determined by monitoring its fluorescence intensity.

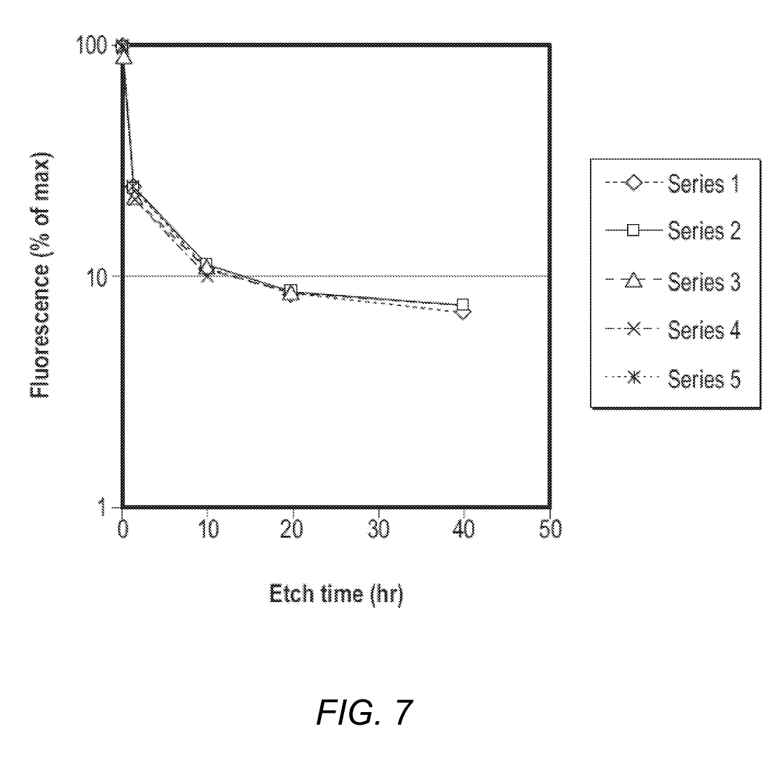

FIG. 7 shows that, after a short initial transient (corresponding to removal of HL-126 from the surface), the infiltrant remains in the pores of the coating for an extended period of time.

The unexpected retention of infiltrant is not believed to be due to material properties of the infiltrant (which etches relatively easily as shown by the initial loss of fluorescence), but rather is determined by the pore structure of the plasma spray coating. The pores are so fine and tortuous that plasma gases cannot get penetrate the cured infiltrant extending into the body of the alumina layer to attack the infiltrant.

Example 4, comparison of methacrylate and epoxy infiltrants.

Both yttria and alumina coatings were formed on aluminum substrates for further evaluation of polymer infiltrants. Yttria coatings were formed utilizing a yttria raw material having particle size within a range of 17-60 microns under the following conditions: torch current of 600 A, argon flow of 25 slm, hydrogen flow of 3.5 slm, helium flow of 35 slm, standoff of 100 mm and a feed rate of 20 g/min. Similarly, alumina coatings were formed from a raw material having a particle size within a range of 15 to 38 microns under the following conditions: a torch current of 600 A, argon flow of 35 slm, hydrogen flow of 13 slm, helium flow of 0 slm, 110 mm standoff and a feed rate of 20 g/min.

The various coated substrates were then subjected to coating processes. Here, methacrylate HL126 liquid was applied onto the yttria and alumina coatings. A vacuum was pulled on the entire sample, and the application and vacuum process was repeated until the surface remained wet, indicating full infiltration into the coating. The methacrylate was cured at 140° C. in an inert environment for 2.5 hours, and excess methacrylate on the coating surface was removed.

Epoxy coating was carried out by pre-heating the yttria and alumina coated samples to 40° C., and applying epoxy liquid onto the coating surface. A vacuum was pulled over the entire sample and the application/vacuum process was repeated until the surface remained wet, indicating full infiltration into the coating. The epoxy was cured at 60° C. in an air environment for 48 hours and excess epoxy was removed after curing. The polymer infiltrant properties are summarized below in Table 2.

TABLE 2
Infiltrant Properties

| | Methacrylate | Epoxy |
|---|---|---|
| Viscosity (cps) | 12 | 60 at 40° C. |
| Curing Shrinkage (%) | ~10 | <3 |
| Cure Temp (° C.) | 140 | 60 |
| Substrate Warpage | Moderate | Low |

The thus coated and infiltrated samples were then characterized as summarized below in Table 3.

TABLE 3
Coating Properties

| | Y₂O₃ Coating | | | Al₂O₃ Coating | |
|---|---|---|---|---|---|
| | As- | | Epoxy | As- | |
| | Sprayed | Methacrylate Sealed | Sealed | Sprayed | Epoxy Sealed |
| Coating Thickness (mm) | 201 | 235 | 200 | 533 | 544 |
| Coating Porosity (%) | 3-4 | | | 4-5 | |
| Dielectric Strength (V/mil) | 717 | 1115 | 1013 | 335 | 635 |
| Resistivity (ohm-cm) | 5.8E+11 | 9.5E+13 | 1.6E+14 | 3.0E+10 | 2.9E+14 |

The coating thickness values are based upon Eddy Current analysis. Coating porosity was measured by image analysis. Dielectric strength and resistivity were measured according to ASTM D3755 and ASTM D257, respectively.

As summarized above, both the methacrylate and epoxy samples showed marked improvement in performance of the substrate, characterized by notably enhanced dielectric strength. However, it is noted that the epoxy samples cured at lower temperatures demonstrated reduced substrate warpage when aluminum metal substrates were used. This was rather unexpected, as the volume of epoxy is small compared to the volume of coating or substrate, and its modulus is very low. The lack of warpage is particularly desirable for making large (>500 mm) parts, as a small angular bend corresponds to a large linear displacement. Additionally, testing was done on room temperature, solvent-based infiltrants, particularly Dichtol 1532. It was found that solvent-based cured infiltrants generally have notable curing shrinkage associated with volatilization of the solvent. It was found that such infiltrants only provided moderate improvements in dielectric strength relative to the thermally cured infiltrants such as acrylates and epoxies. Accordingly, thermally curable infiltrants may be particularly useful for certain applications.

Example 5, additional characterization.

Both yttria and alumina coatings were formed on aluminum substrates for further evaluation of polymer infiltrants. Both yttria and alumina coatings were formed on aluminum substrates for further evaluation of polymer infiltrants. The thus coated and infiltrated samples were then characterized as summarized below in Table 4.

TABLE 4
Coating Properties

| | Y₂O₃ Coating | | | | |
|---|---|---|---|---|---|
| | (200 um thickness) | | Al₂O₃ Coating | | |
| | As- | | Coating | As- | Epoxy |
| | Sprayed | Epoxy Sealed | Thickness | Sprayed | Sealed |
| Acid Etch Resistance (min) | 500 | 1393 | | | |
| Liquid Particle Count | 35,000 | 3,800 | | | |
| (particles/cm²) | | | | | |
| Hardness (GPa) | 4.3 | 4.9 | 500 um | 10.5 | 10.8 |
| Young's Modulus (GPa) | 69 | 85 | 500 um | 122 | 154 |
| Adhesion Strength (MPa) | | | | | |
| Bare Aluminum | 27 | 63 | 100 um | 29 | 66 |
| Anodized Aluminum | | | 100 um | 67 | 81 |
| Anodized Aluminum | | | 500 um | 8 | 65 |

The Adhesion Strength values are measured according to ASTM C633. Hardness is measured according to Vickers Indent at 300 g, and Young's Modulus is measured according to Knoop Indent at 200 g. Acid Etch Resistance is based upon the time to generate significant bubbling in HCl, using a solution consisting of 10% concentrated HCl (37 wt % HCl) and 90% water, the test being done at room temperature. For the liquid particle count measurement, coated φ8″ coupons, having a 200 um yttria coating, are subjected to an ultrasonic bath for 30 minutes. The number of particles having a size greater than 0.2 microns that were dislodged by the ultrasonic treatment is determined to obtain the Liquid Particle Count. The particle count measurement was done by Metron Technologies of Freemont, Calif. (Post-clean UPW extractable Laser Particle analysis, Metron item ID 85322 CTQ1).

Plate Warpage is a standardized measurement of dimensional impact of the thermally sprayed layer containing sealant. Plate Warpage is the value of bow (peak to valley) from the center of a standardized plate to a corner of the standardized plate. The standardized plate is a 0.5 m×0.5 m×39 mm 5052 aluminum plate, thermally spayed to obtain a thermally sprayed layer having a standardized thickness of 1.3 mm. The coating includes top and bottom alumina coating and a thin plasma sprayed tungsten electrode layer. The coating is subjected to infiltration and curing of the infiltrant.

A methacrylate sealed (cure temperature of 140 C) thermally sprayed layer was found to have a Plate Warpage of 250 microns. An epoxy sealed (cure temperature 60 C) was found to have a Plate Warpage of between 100 microns to 150 microns.

As summarized above, the epoxy samples showed marked improvement in performance of the substrate, characterized by notably reduced liquid particle count and improved resistance to acid etching.

As should be clear based on the disclosure herein, particular embodiments are drawn to electrostatic chucks that have at least one porous layer having pores forming interconnected porosity. That layer, generally at least the dielectric layer, contains a cured polymer infiltrant that surprisingly improves dielectric breakdown properties of the layer. The foregoing approach is in direct contrast to state of the art approaches that focus on 100% dense layers for proper dielectric functionality. Without wishing to be tied to any particular theory, it is believed that the cured infiltrant remaining in the interconnected porosity reduces charge flow along interior pore surfaces, which contribute to poor dielectric properties in porous dielectric materials.

In addition, it has been found that embodiments demonstrate improved mechanical robustness, as use of porous layer(s), even when infiltrated with a cured polymer infiltrant, are less susceptible to failure based on induced strain, such as due to thermal expansion mismatches between the layer(s) and an underlying base, for example.

While the invention has been illustrated and described in the context of specific embodiments, it is not intended to be limited to the details shown, since various modifications and substitutions can be made without departing in any way from the scope of the present invention. For example, additional or equivalent substitutes can be provided and additional or equivalent production steps can be employed. As such, further modifications and equivalents of the invention herein disclosed may occur to persons skilled in the art using no more than routine experimentation, and all such modifications and equivalents are believed to be within the scope of the invention as defined by the following claims.

1. The processing device of claim 13, wherein the sealant is a
thermally cured sealant cured at a temperature of not greater than about 100° C.

2. The processing device of claim 1, wherein the surface coating has a Liquid Particle Count of not greater than about 10,000 particles/cm².

3. (canceled)

4. The processing device of claim 1, wherein the dielectric material has an acid etch resistance rating of at least about 750 minutes.

5. The processing device of claim 1, wherein the surface coating has a porosity of not less than 1 vol %.

6. The processing device of claim 1, wherein the surface coating has an average pore size of not greater than 200 nm

7. The processing device of claim 1, wherein the surface coating is comprised of a thermally sprayed layer having splat formations, the pores being interconnected and extending between the splat formations or through cracks present in the splat formations.

8. The processing device of claim 1, wherein the dielectric layer comprises a dielectric material selected from the group consisting of aluminum-containing oxides, silicon-containing oxides, zirconium-containing oxides, titanium-containing oxides, yttrium-containing oxides, and combinations or compound oxides thereof.

9. The processing device of claim 1, wherein the surface coating has an average thickness of not less than about 100 microns.

10. The processing device of claim 15, wherein the epoxy resin has
a viscosity of not greater than 500 cP in liquid precursor form.

11. (canceled)

12. The processing device of claim 10, wherein the liquid precursor form has a viscosity of greater than 50 cP during infiltrating.

13. A processing device comprising:
a plurality of walls defining an interior space configured to be exposed to plasma;
a surface coating on the interior surface of at least one of the plurality of walls, the surface coating comprising pores forming interconnected porosity, and
a low shrinkage sealant residing in at least a portion of the pores of the surface coating, the low shrinkage sealant characterized by a solidification shrinkage of not greater than 8%.

14. (canceled)

15. The processing device of claim 13, wherein the low shrinkage sealant comprises epoxy resin.

16. The processing device of claim 13, wherein the low shrinkage sealant occupies at least 40 vol % of the total pore volume of the surface coating.

17. (canceled)

18. (canceled)

19. (canceled)

20. (canceled)

21. (canceled)

22. (canceled)

23. (canceled)

24. (canceled)

25. (canceled)

26. (canceled)

27. The method of claim 31, wherein the
infiltrant comprising a thermally curable sealant; and
curing the infiltrant occurs at a cure temperature not greater than about 100° C.

28. The method of claim 27, wherein the cure temperature is not greater than 80° C.

29. (canceled)

30. (canceled)

31. A method of forming a plasma resistant coating comprising:
providing a substrate;
forming a surface coating overlying the substrate, the surface coating comprising pores forming interconnected porosity;
infiltrating the surface coating with an infiltrant comprising a low shrinkage sealant, the low shrinkage sealant characterized by a solidification shrinkage of not greater than 8%; and
curing the infiltrant, such that the low shrinkage sealant is left to reside in at least a portion of the pores.

32. (canceled)

33. (canceled)

34. (canceled)

35. The method of claim 31, wherein the
sealant has a viscosity of not greater than 500 cP in liquid precursor form.

36. (canceled)

37. (canceled)

38. (canceled)

39. (canceled)

40. (canceled)

41. (canceled)

42. (canceled)

43. (canceled)

44. An electrostatic chuck comprising:
an insulating layer;
a conductive layer overlying the insulating layer;
a dielectric layer overlying the conductive layer, the dielectric layer having a porosity not less than 2 vol %, wherein the dielectric layer has a dielectric strength per unit thickness greater than 10 V/micrometer and a Liquid Particle Count of not greater than 10,000 particles/cm².

45. The electrostatic chuck of claim 44, wherein at least one of (i) the insulating layer has a surface with an aspect ratio of at least about 1.1, and the conductive layer overlies the surface, or (ii) the electrostatic chuck has an outer peripheral surface and the conductive layer is embedded within the electrostatic chuck such that an outer peripheral edge of the conductive layer is at least about 1 mm from the outer peripheral surface.

46. (canceled)

47. The processing device of claim 1
wherein the sealant has a Plate Warpage of not greater than 200 microns.

48. The processing device of claim 44
wherein the electrostatic chuck has a warp of less than 200 um over a length of 700 mm.

49. The electrostatic chuck of claim 48, wherein the electrostatic chuck has a thickness of less than 50 mm.

50. The processing device of claim 44
wherein the electrostatic chuck has a Normalized Warp of less than 33.

51. The processing device of claim 13, wherein processing device is an plasma resistant component.
